(19) United States
(12) Patent Application Publication
(10) Pub. No.: US 2026/0013253 A1
(43) Pub. Date: Jan. 8, 2026

(54) IMAGE SENSOR

(71) Applicant: VisEra Technologies Company Ltd., Hsin-Chu City (TW)

(72) Inventors: Yao-Chung TUNG, Hsin-Chu City (TW); Shin-Hong KUO, Hsin-Chu City (TW); Huang-Jen CHEN, Hsin-Chu City (TW); Ching-Chiang WU, Hsin-Chu City (TW); Han-Lin WU, Hsin-Chu City (TW); Hung-Jen TSAI, Hsin-Chu City (TW)

(21) Appl. No.: 19/020,203

(22) Filed: Jan. 14, 2025

Related U.S. Application Data
(60) Provisional application No. 63/667,920, filed on Jul. 5, 2024.

(51) Int. Cl. H10F 39/00; H10F 39/18

(52) U.S. Cl. CPC H10F 39/8063; H10F 39/182

(57) ABSTRACT

The present disclosure provides an image sensor including a photodiode layer, a color filter layer on the photodiode layer, and an optical layer on the color filter layer. The optical layer includes a spread layer, a first transparent layer above the spread layer, a buffer layer covering a top surface of the first transparent layer, a first microstructure layer including first microstructures embedded in a lower portion of the first transparent layer, and a second microstructure layer including second microstructures at least partially embedded in an upper portion of the first transparent layer. The first microstructure layer and the second microstructure layer are separated by the first transparent layer and the buffer layer. A refractive index of the first microstructure layer and the second microstructure layer is larger than refractive indexes of the first transparent layer and the spread layer.

### CROSS-REFERENCE TO RELATED APPLICATION

This application claims priority to U.S. Provisional Application Ser. No. 63/667,920, filed Jul. 5, 2024, which is herein incorporated by reference in its entirety.

### BACKGROUND

### Field of Invention

The present disclosure relates to the image sensor. More particularly, the present disclosure relates to the image sensor having microstructure enhanced quantum efficiency.

### Description of Related Art

In the field of complementary metal oxide semiconductor (CMOS) image sensor (CIS), the arrangements and dimensions of components in the image sensor would affect the distribution of incident light. If the incident lights with different wavelengths are not properly modulated, the incident lights may be distributed into undesired regions and lead to the poor quantum efficiency of the CIS device. Therefore, there is a need for an image sensor with high effective dispersion of incident light to improve the quantum efficiency of the image sensor.

### SUMMARY

According to one embodiment of the present disclosure, an image sensor includes a photodiode layer, a color filter layer on the photodiode layer, and an optical layer on the color filter layer. The optical layer includes a spread layer, a first transparent layer above the spread layer, a buffer layer covering a top surface of the first transparent layer, a first microstructure layer including first microstructures embedded in a lower portion of the first transparent layer, and a second microstructure layer including second microstructures at least partially embedded in an upper portion of the first transparent layer. The first microstructure layer and the second microstructure layer are separated by the first transparent layer and the buffer layer. A refractive index of the first microstructure layer and the second microstructure layer is larger than refractive indexes of the first transparent layer and the spread layer.

In some embodiments, a refractive index of the buffer layer is smaller than the refractive index of the first microstructure layer and the second microstructure layer but larger than the refractive indexes of the first transparent layer and the spread layer.

In some embodiments, the refractive indexes of the first transparent layer and the spread layer are larger than a refractive index of air.

In some embodiments, a thickness of the first transparent layer between a top surface of the first microstructure layer and the buffer layer below a bottom surface of the second microstructure layer is smaller than or equal to an absorption wavelength of the photodiode layer.

In some embodiments, each of the first microstructures stands on a top facet of the spread layer. A top surface of the top facet is higher than a top surface of a remaining portion of the spread layer.

In some embodiments, a thickness of the remaining portion of the spread layer is smaller than or equal to three times of an absorption wavelength of the photodiode layer.

In some embodiments, the top surface of the top facet is higher than the top surface of the remaining portion by a distance smaller than or equal to half of a height of the first microstructures.

In some embodiments, a top surface of the second microstructure layer is lower than a top surface of the buffer layer by a distance smaller than or equal to half of a height of the second microstructures.

In some embodiments, a top surface of the second microstructure layer is higher than a top surface of the buffer layer by a distance smaller than or equal to a height of the second microstructures.

In some embodiments, each of the second microstructures has a bottom width smaller than or equal to a top width, a height smaller than or equal to eight times of the top width, and an angle between a sidewall and a bottom surface in a range of 90° to 160°.

In some embodiments, each of the first microstructures has a top width smaller than or equal to a bottom width, a height smaller than or equal to eight times of the bottom width, and an angle between a sidewall and a bottom surface in a range of 50° to 90°.

In some embodiments, each of the first microstructures and the second microstructures has a flat tip, a diamond tip, or a rounding tip.

In some embodiments, the buffer layer conformally covers the top surface of the first transparent layer, sidewalls of the second microstructures, and bottom surfaces of the second microstructures.

In some embodiments, the buffer layer has a portion below bottom surfaces of the second microstructures that is thicker than a portion of the buffer layer on sidewalls of the second microstructures.

In some embodiments, the image sensor further includes a second transparent layer interposed between the spread layer and the first transparent layer and a third microstructure layer including third microstructures embedded in a lower portion of the second transparent layer. A refractive index of the third microstructure layer is the same as the refractive index of the first microstructure layer and larger than a refractive index of the second transparent layer.

In some embodiments, a thickness of the second transparent layer between a top surface of the third microstructure layer and a top surface of the second transparent layer is smaller than or equal to an absorption wavelength of the photodiode layer.

In some embodiments, the color filter layer includes a first color filter and a second color filter adjacent to the first color filter. A distance between a center of one of the second microstructures nearest to an edge of the first color filter and the edge of the first color filter is different from a distance between a center of one of the second microstructures nearest to an edge of the second color filter and the edge of the second color filter.

In some embodiments, an edge of the optical layer is offset from an edge of the color filter layer.

In some embodiments, the image sensor further includes a protection layer covering a top surface of the second microstructure layer and having a flat top surface.

In some embodiments, the color filter layer includes a first color filter and a second color filter adjacent to the first color filter. A pattern of the second microstructures above the first color filter is different from a pattern of the second microstructures above the second color filter.

According to the above-mentioned embodiments, the image sensor includes the optical layer including a spread layer, a transparent layer, and at least two microstructure layers, where the microstructures of the two microstructure layers are embedded in and separated by the transparent layer. The refractive index of the microstructure layers is larger than the refractive indexes of the transparent layer and the spread layer to provide the light dispersion function of the optical layer, thereby improving the quantum efficiency of the image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an image sensor according to one embodiment of the present disclosure.

FIG. 2 illustrates light paths in the cross-sectional view of the image sensor shown in FIG. 1.

FIGS. 3A-3G illustrate cross-sectional views of second microstructures according to some embodiments of the present disclosure.

FIG. 4 illustrates a cross-sectional view of a first microstructure according to one embodiment of the present disclosure.

FIGS. 5A-5F illustrate three-dimensional views of first microstructures and second microstructures according to some embodiments of the present disclosure.

FIGS. 6A-6C illustrate cross-sectional views of first microstructures and second microstructures according to some embodiments of the present disclosure.

FIG. 7, FIGS. 8A-8B, and FIGS. 9A-9B illustrate cross-sectional views of image sensors according to some embodiments of the present disclosure.

FIGS. 10A-10D illustrate top views of second microstructures and color filter layers according to some embodiments of the present disclosure.

FIGS. 11A-11H illustrate cross-sectional views of an image sensor at various stages in a manufacturing process according to some embodiments of the present disclosure.

### DETAILED DESCRIPTION

The following disclosure provides many different embodiments, or examples, for implementing different features of the provided subject matter.

Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to some embodiments of the present disclosure, an image sensor includes an optical layer including a spread layer, a transparent layer, and at least two microstructure layers, where the microstructures of the two microstructure layers are embedded in and separated by the transparent layer. The refractive index of the microstructure layers is larger than the refractive indexes of the transparent layer and the spread layer to disperse the incident light into the corresponding color filters below, thereby improving the quantum efficiency of the image sensor.

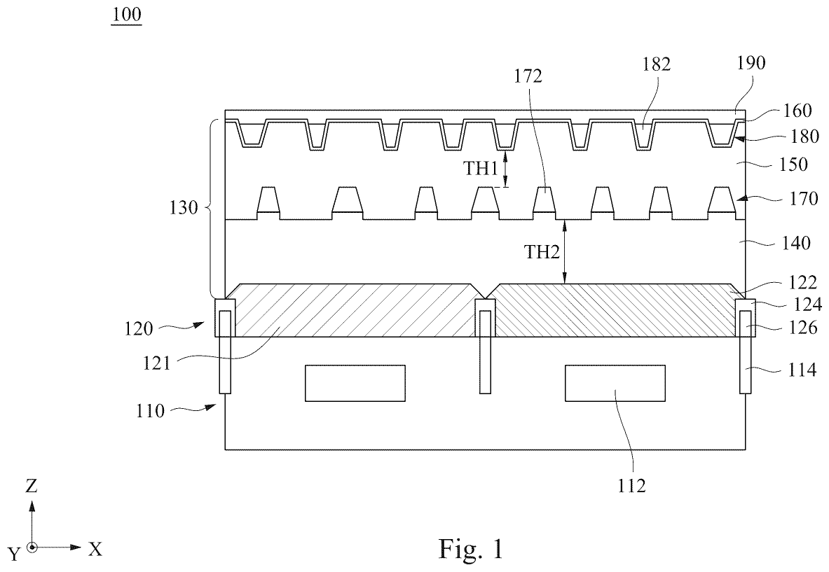

According to one embodiment of the present disclosure, FIG. 1 illustrates a cross-sectional view of an image sensor 100 in the X-Z plane. The image sensor 100 includes a photodiode layer 110, a color filter layer 120 on the photodiode layer 110, and an optical layer 130 on the color filter layer 120. The incident light for the image sensor 100 is first dispersed by the optical layer 130, filtered by the color filter layer 120, and then converted into electric signal by the photodiode layer 110.

Specifically, the photodiode layer 110 includes a plurality of photodiodes 112 and a plurality of isolation structures 114 separating the photodiodes 112 from each other. The color filter layer 120 includes a plurality of color filters, such as a first color filter 121 corresponding to a first wavelength range and a second color filter 122 corresponding to a second wavelength range different from the first wavelength range. Each of the color filters of the color filter layer 120 overlies at least one photodiode 112, so the incident light reaching the photodiode 112 is first filtered by the color filter layer 120. In some embodiments, the color filters of the color filter layer 120 may be separated by the isolation grid 124, where a metal grid 126 in the isolation grid 124 may include a light absorbing metal, such as W, TiN, Cu, or Al.

The optical layer 130 includes a spread layer 140, a first transparent layer 150 above the spread layer 140, a buffer layer 160 on the first transparent layer 150, a first microstructure layer 170 between the spread layer 140 and the first transparent layer 150, and a second microstructure layer 180 on the buffer layer 160. The first microstructure layer 170 and the second microstructure layer 180 are separated by the first transparent layer 150 and the buffer layer 160, while the first transparent layer 150 and the second microstructure layer 180 are separated by the buffer layer 160. In the embodiments which the first transparent layer 150 is directly on the spread layer 140, the bottom surface of the first transparent layer 150 may contact the top surface of the spread layer 140.

More specifically, the first microstructure layer 170 includes a plurality of first microstructures 172 embedded in a lower portion of the first transparent layer 150, where the bottom surfaces of the first microstructures 172 contact the top surface of the spread layer 140. The first microstructures 172 extend upwardly from the spread layer 140 into the first transparent layer 150, so the first microstructures 172 may be referred to as “tower shape microstructures”. The second microstructure layer 180 includes a plurality of second microstructures 182 embedded in an upper portion of the first transparent layer 150, where the bottom surfaces and the sidewalls of the second microstructures 182 contact the buffer layer 160. The top surfaces of the first microstructures 172 and the bottom surfaces of the second microstructures 182 are separated by the first transparent layer 150 and the buffer layer 160. The second microstructures 182 extend downwardly from the top surface of the optical layer 130 into the first transparent layer 150, so the second microstructures 182 may be referred to as “funnel shape microstructures”.

Although the first microstructures 172 are illustrated as individual microstructures separated from each other, the first microstructures 172 are formed in a same level of the optical layer 130 by the same process/such that the first microstructures 172 may be collectively considered as a layer (i.e., the first microstructure layer 170). Similarly, the individual second microstructures 182 in a same level in FIG. 1 may be collectively considered as the second microstructure layer 180.

The layers in the optical layer 130 have different refractive indexes to adjust the phase of the incident light. Particularly, a refractive index of the first microstructure layer 170 and a refractive index of the second microstructure layer 180 are larger than a refractive index of the spread layer 140 and a refractive index of the first transparent layer 150. A refractive index of the buffer layer 160 is smaller than the refractive index of the second microstructure layer 180 but larger than the refractive indexes of the spread layer 140 and the first transparent layer 150. The optical layer 130 having the above-mentioned refractive indexes may refract various wavelengths of the incident light in different angles, thereby dispersing the wavelengths into the corresponding color filters of the color filter layer 120 and improving the quantum efficiency of the image sensor 100.

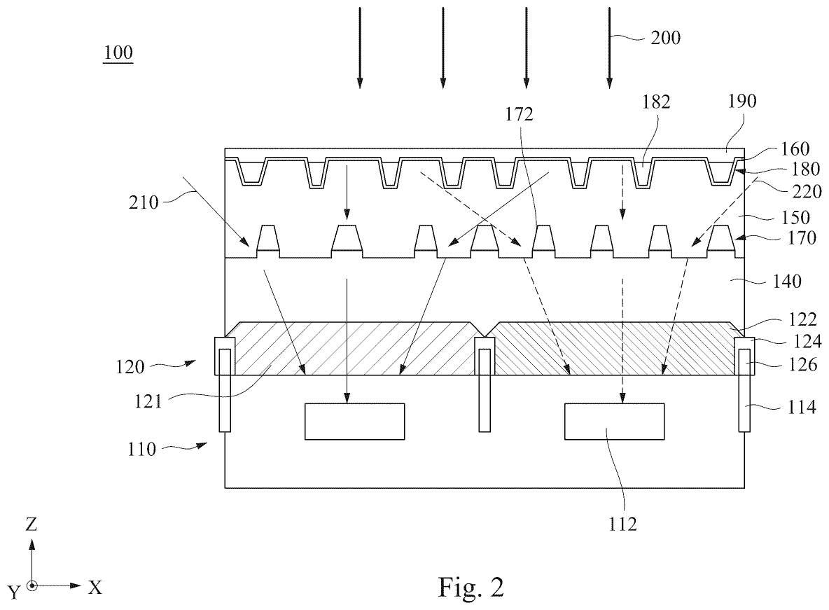

As an exemplary illustration of the light dispersion function of the optical layer 130, FIG. 2 illustrates the light paths in the cross-sectional view of the image sensor 100 shown in FIG. 1. The incident light 200 includes a first wavelength 210 within the first wavelength range of the first color filter 121 and a second wavelength 220 within the second wavelength range of the second color filter 122. As the incident light 200 sequentially passes through the second microstructure layer 180 with high refractive index, the first transparent layer 150 with low refractive index, the first microstructure layer 170 with high refractive index, and the spread layer 140 with low refractive index, the first wavelength 210 and the second wavelength 220 are refracted in different angles. As a result, the first wavelength 210 originally above the second color filter 122 may be refracted into the first color filter 121, while the second wavelength 220 originally above the first color filter 121 may be refracted into the second color filter 122.

After the light dispersion in the optical layer 130, the incident light 200 is easily dissociated into different wavelengths, and each wavelength is directed into the corresponding transmittable one of the color filters even if the corresponding color filter is not on the extended line of the original incident light 200. Compared to the image sensor without the optical layer 130, the photodiode 112 of the image sensor 100 may receive more light within the wavelength range of the color filter overlying the photodiode 112. In other words, the optical layer 130 provides high effective dispersion of the incident light 200, thereby increasing the quantum efficiency of the image sensor 100.

In some embodiments, the first microstructure layer 170 and the second microstructure layer 180 may have a same refractive index. For example, the first microstructure layer 170 and the second microstructure layer 180 may be made of a same material having the refractive index larger than 1.5. The spread layer 140 and the first transparent layer 150 may have different refractive indexes, where the refractive indexes of the spread layer 140 and the first transparent layer 150 are both larger than the refractive index of air. For example, the refractive indexes of the spread layer 140 and the first transparent layer 150 may be larger than 1, while these refractive indexes may be equal to or smaller than 1.7.

In addition to the refractive indexes of the optical layer 130, the contour and the arrangement of the first microstructures 172 and the second microstructures 182 may also affect the light dispersion function of the optical layer 130. The first microstructures 172 and the second microstructures 182 embedded in the first transparent layer 150 allows more flexible design in the dimension, shape, and pattern of the microstructures, such that the optical layer 130 may be compatible with various layouts of the color filter layer 120 and the photodiode layer 110.

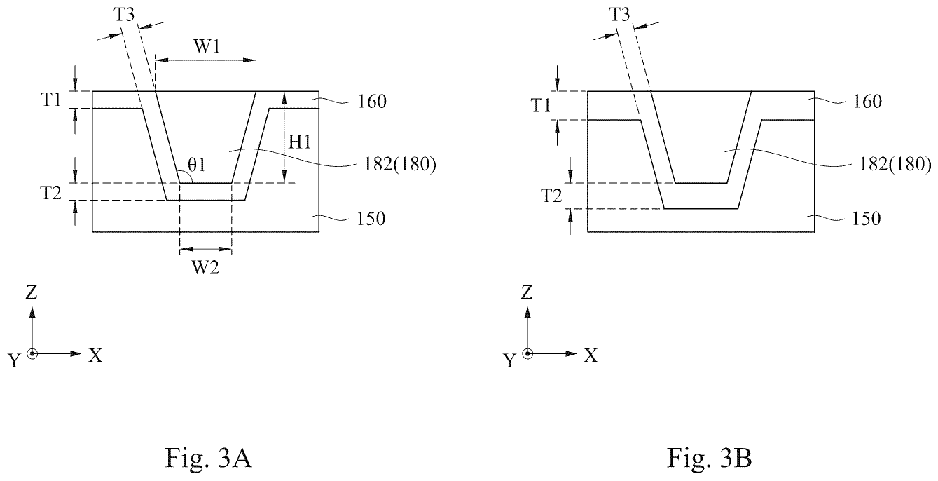

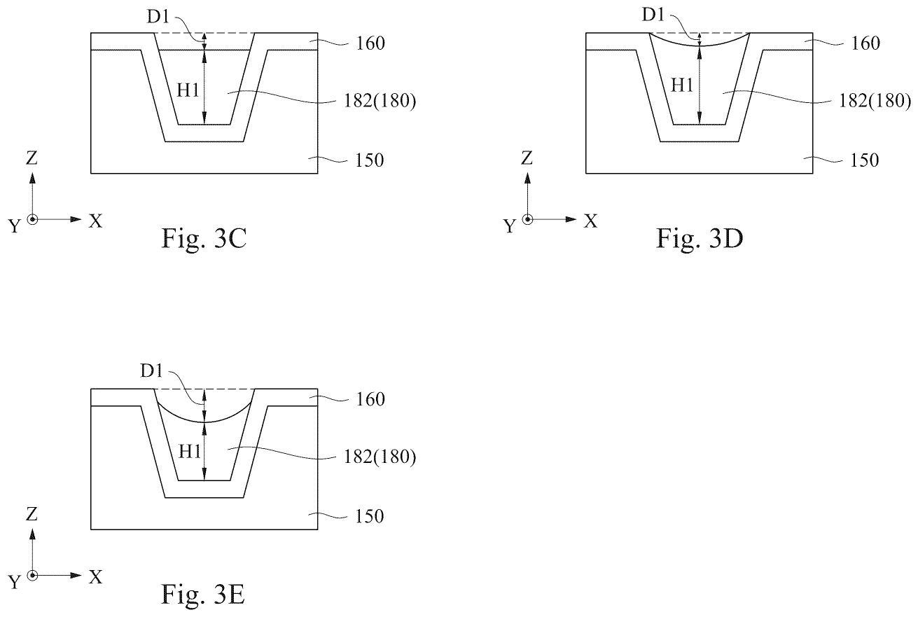

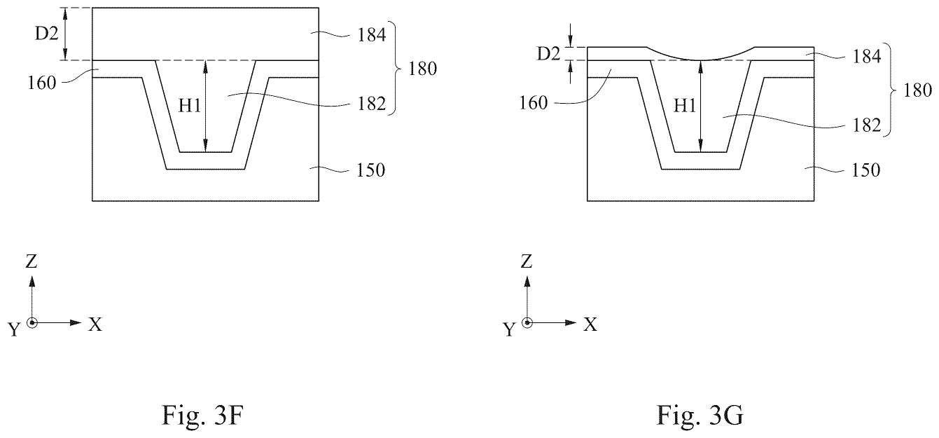

According to one embodiment of the present disclosure, FIG. 3A illustrates a cross-sectional view of a second microstructure 182 surrounded by the buffer layer 160 and the first transparent layer 150 in the X-Z plane. The second microstructure 182 has a top width W1 and a bottom width W2 along the X-axis direction, where the bottom width W2 is smaller than the top width W1 to provide a trapezoid cross-section of the second microstructure 182. In some other embodiments, the bottom width W2 may be equal to the top width W1 to provide a rectangular cross-section of the second microstructure 182. The angle θ1 between the sidewall and the bottom surface of the second microstructure 182 is in a range of 90° to 160°. The height H1 of the second microstructure 182 along the Z-axis direction is smaller than or equal to eight times of the top width W1.

In the embodiments illustrated in FIG. 3A, the buffer layer 160 conformally covers the top surface of the first transparent layer 150, the sidewalls of the second microstructure 182, and the bottom surface of the second microstructure 182. In other words, the buffer layer 160 has a thickness T1 on the top surface of the first transparent layer 150, a thickness T2 below the bottom surface of the second microstructure 182, and a thickness T3 on the sidewalls of the second microstructure 182, where the thickness T1 is the same as the thickness T2 and the thickness T3.

In some other embodiments, the buffer layer 160 may non-conformally covers the top surface of the first transparent layer 150, the sidewalls of the second microstructure 182, and the bottom surface of the second microstructure 182. According to another embodiment of the present disclosure, FIG. 3B illustrates a cross-sectional view of a second microstructure 182 surrounded by the buffer layer 160 and the first transparent layer 150 in the X-Z plane. The buffer layer 160 in FIG. 3B has the thickness T1 on the top surface of the first transparent layer 150 thicker than the thickness T3 on the sidewalls of the second microstructure 182. The buffer layer 160 also has the thickness T2 below the bottom surface of the second microstructure 182 thicker than the thickness T3 on the sidewalls of the second microstructure 182. It should be noted that the non-conformal buffer layer 160 illustrated in FIG. 3B is an example and is not intended to be limiting the scope of the present disclosure.

FIGS. 3A-3B illustrate the second microstructure 182 having the top surface levelled with the top surface of the buffer layer 160. According to some embodiments of the present disclosure, FIGS. 3C-3G illustrate the cross-sectional views of the second microstructures 182 with a variety of top surfaces in the X-Z plane. In FIGS. 3C-3E, the top surface of the second microstructure 182 (i.e., the top surface of the second microstructure layer 180) is lower than the top surface of the buffer layer 160. The second microstructure 182 in FIG. 3C has the top surface parallel with the top surface of the buffer layer 160, where a distance D1 between the top surface of the second microstructure 182 and the top surface of the buffer layer 160 along the Z-axis direction is smaller than or equal to half of the height H1 of the second microstructure 182. The second microstructures 182 in FIGS. 3D-3E have the concave top surface recessed toward the first transparent layer 150, where a center of the top surface of the second microstructure 182 is lower than the top surface of the buffer layer 160 by a distance D1 smaller than or equal to half of the height H1 of the second microstructure 182.

In FIGS. 3F-3G, the top surface of the second microstructure layer 180 is higher than the top surface of the buffer layer 160. Particularly, the second microstructure layer 180 in FIGS. 3F-3G includes an excessive portion 184 on the second microstructure 182, where the second microstructure 182 and the excessive portion 184 may be a continuous material layer. The top surface of the excessive portion 184 (i.e., the top surface of the second microstructure layer 180) is higher than the top surface of the buffer layer 160 by a distance D2 smaller than or equal to the height H1 of the second microstructure 182. The second microstructure layer 180 in FIG. 3F has the planar top surface parallel with the top surface of the buffer layer 160, and the second microstructure layer 180 in FIG. 3G has the top surface with a concave portion recessed toward the first transparent layer 150.

The second microstructures 182 in FIGS. 3A-3E may be considered as fully embedded microstructures in the first transparent layer 150, while the second microstructures 182 in FIGS. 3F-3G may be considered as partially embedded microstructures since there is no obvious interface between the second microstructure 182 and the excessive portion 184. It should be noted that the second microstructures 182 illustrated in FIGS. 3A-3G are merely examples and are not intended to be limiting the scope of the present disclosure.

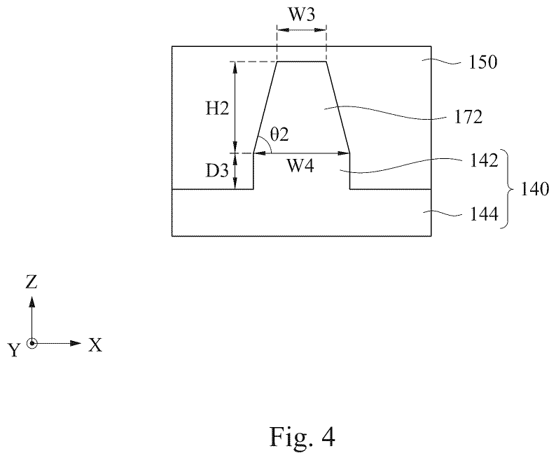

According to some embodiments of the present disclosure, FIG. 4 illustrates a cross-sectional view of a first microstructure 172 disposed on the spread layer 140 and surrounded by the first transparent layer 150 in the X-Z plane. The first microstructure 172 has a top width W3 and a bottom width W4 along the X-axis direction, where the top width W3 is smaller than the bottom width W4 to provide a trapezoid cross-section of the first microstructure 172. In some other embodiments, the top width W3 may be equal to the bottom width W4 to provide a rectangular cross-section of the first microstructure 172. The angle θ2 between the sidewall and the bottom surface of the first microstructure 172 is in a range of 50° to 90°. The height H2 of the first microstructure 172 along the Z-axis direction is smaller than or equal to eight times of the bottom width W4.

In some embodiments, the top surface of the spread layer 140 may include a top facet 142 and a remaining portion 144 adjacent to the top facet 142, where the top surface of the top facet 142 is higher than the top surface of the remaining portion 144 by a distance D3 smaller than or equal to half of the height H2 of the first microstructure 172. The first microstructure 172 stands on the top facet 142. The bottom width W4 of the first microstructure 172 is smaller than or equal to the width of the top facet 142 along the X-axis direction. As a result, the bottom surface of the first microstructure 172 is higher than the top surface of the remaining portion 144.

The shape of the first microstructure 172 and the second microstructure 182 may depend on the light dispersion requirement of the optical layer.

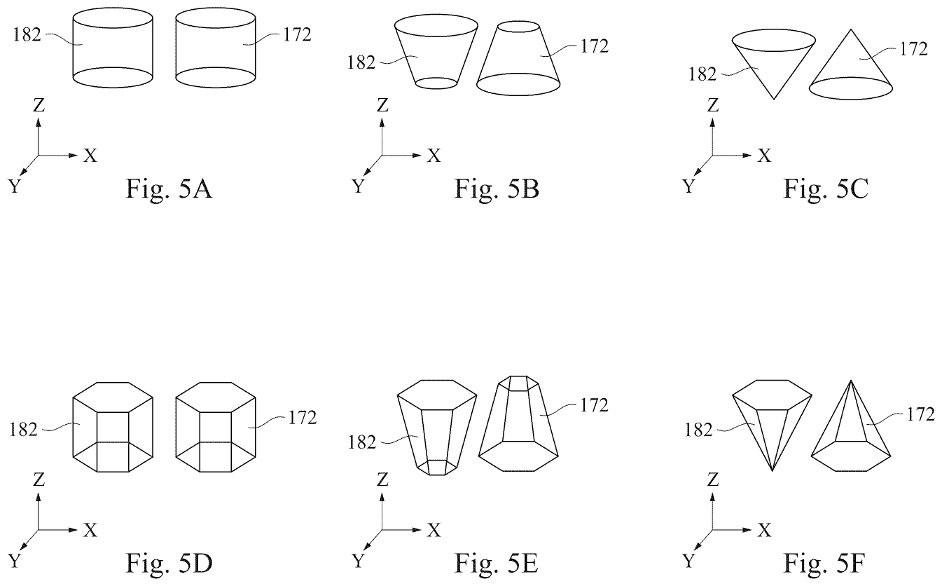

According to some embodiments of the present disclosure, FIGS. 5A-5F illustrate the three-dimensional views of the first microstructure 172 and the second microstructure 182. The first microstructure 172 and the second microstructure 182 in FIGS. 5A-5C have rounded cross-sections parallel to the incident surface of the optical layer, where the microstructures in FIG. 5A have a cylinder shape, the microstructures in FIG. 5B have a conical frustum shape, and the microstructures in FIG. 5C have a conical cone shape. The first microstructure 172 and the second microstructure 182 in FIGS. 5D-5F have polygonal cross-sections parallel to the incident surface of the optical layer, where the microstructures in FIG. 5D have a pillar shape, the microstructures in FIG. 5E have a frustum shape, and the microstructures in FIG. 5F have a pyramid shape. Although FIGS. 5A-5F illustrates the first microstructure 172 and the second microstructure 182 having the same shape, the first microstructure 172 and the second microstructure 182 may be a combination of different shapes in some embodiments. It should be noted that the first microstructure 172 and the second microstructure 182 illustrated in FIGS. 5A-5F are merely examples and are not intended to be limiting the scope of the present disclosure.

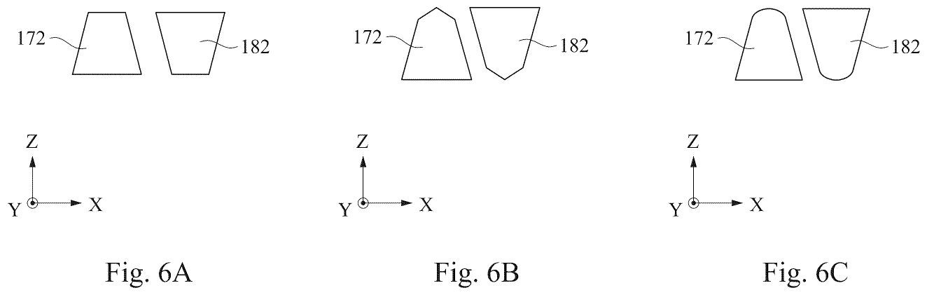

According to some embodiments of the present disclosure, FIGS. 6A-6C illustrate the cross-sectional views of the first microstructure 172 and the second microstructure 182 in the X-Z plane. The first microstructure 172 and the second microstructure 182 are similar in FIGS. 6A-6C, except for the shape of the top surface of the first microstructure 172 and the bottom surface of the second microstructure 182. In FIG. 6A, the top surface of the first microstructure 172 and the bottom surface of the second microstructure 182 have flat tips. In FIG. 6B, the top surface of the first microstructure 172 and the bottom surface of the second microstructure 182 have diamond tips. In FIG. 6C, the top surface of the first microstructure 172 and the bottom surface of the second microstructure 182 have rounding tips. Although FIGS. 6A-6C illustrates the first microstructure 172 and the second microstructure 182 having the same tip, the first microstructure 172 and the second microstructure 182 may be a combination of different tips in some embodiments. It should be noted that the first microstructure 172 and the second microstructure 182 illustrated in FIGS. 6A-6C are merely examples and are not intended to be limiting the scope of the present disclosure.

As mentioned above, the dimension and the shape of the first microstructure 172 may be same as or different from those of the second microstructure 182, depending on the light dispersion requirement of the optical layer. The position arrangement, or referred to as the pattern, of the first microstructures 172 may also be same as or different from that of the second microstructures 182. In addition, the shape and the pattern of the first microstructure 172 and the second microstructure 182 corresponding to the first color filter 121 in FIG. 1 may be different from those of the first microstructure 172 and the second microstructure 182 corresponding to the second color filter 122 due to the different wavelength ranges of the first color filter 121 and the second color filter 122.

Referring back to FIG. 1, the thicknesses of the first transparent layer 150 and the spread layer 140 may also affect the light dispersion function of the optical layer 130. Specifically, the thicknesses of the first transparent layer 150 and the spread layer 140 are mainly based on the absorption wavelength of the photodiode 112 in the photodiode layer 110. For example, the thickness TH1 of the first transparent layer 150 between the top surface of the first microstructure layer 170 and the buffer layer 160 below the bottom surface of the second microstructure layer 180 along the Z-axis direction may be smaller than or equal to the absorption wavelength of the photodiode layer 110. The thickness TH2 of the spread layer 140 between its top surface not covered by the first microstructures 172 (i.e., the top surface of the remaining portion 144) and the color filter, such as the first color filter 121 or the second color filter 122, may be smaller than or equal to three times of the absorption wavelength of the photodiode layer 110.

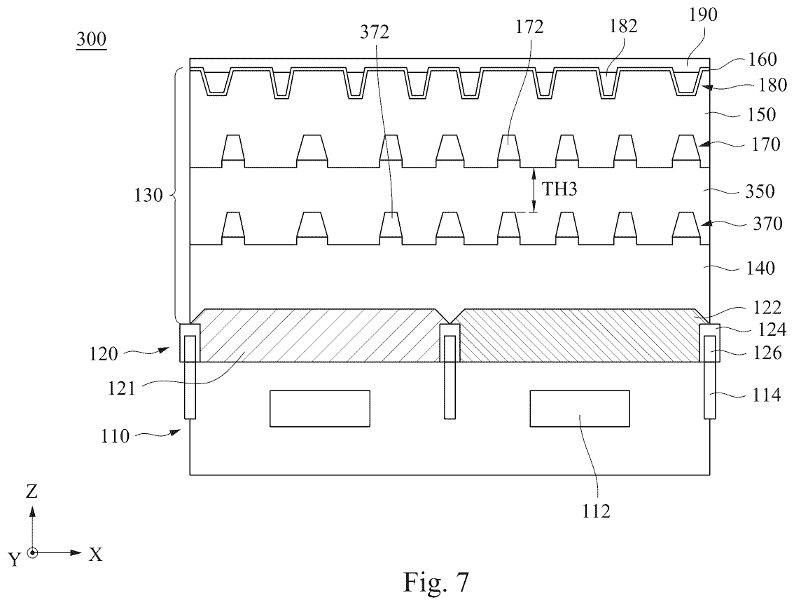

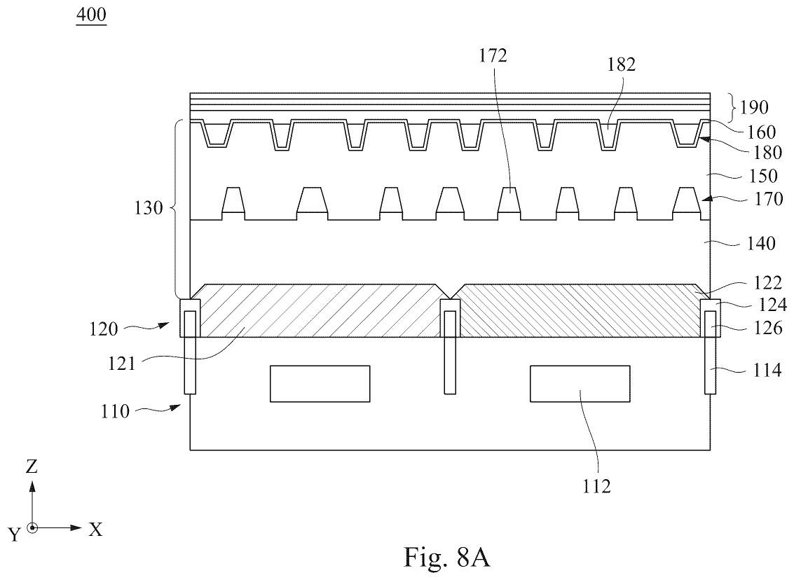

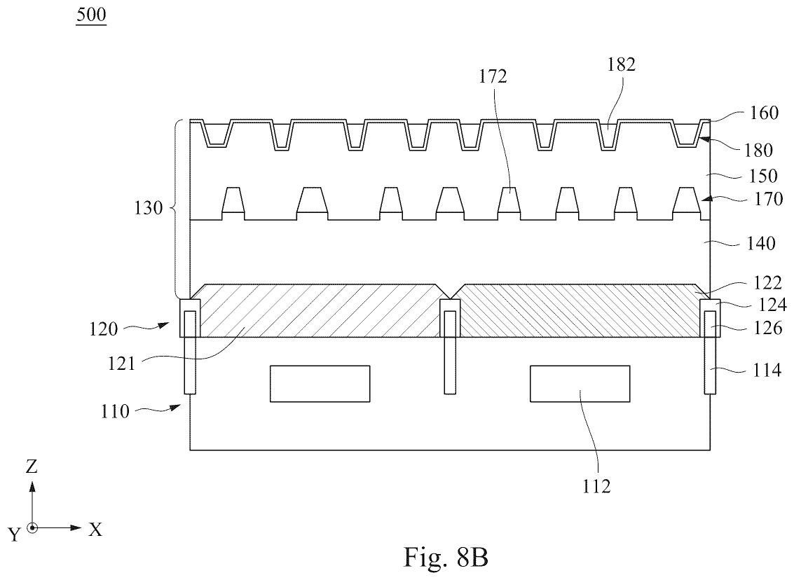

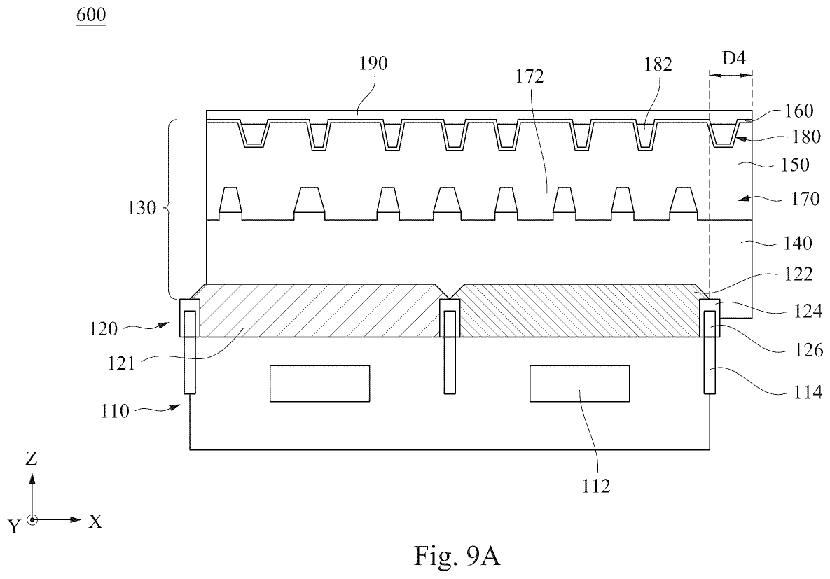

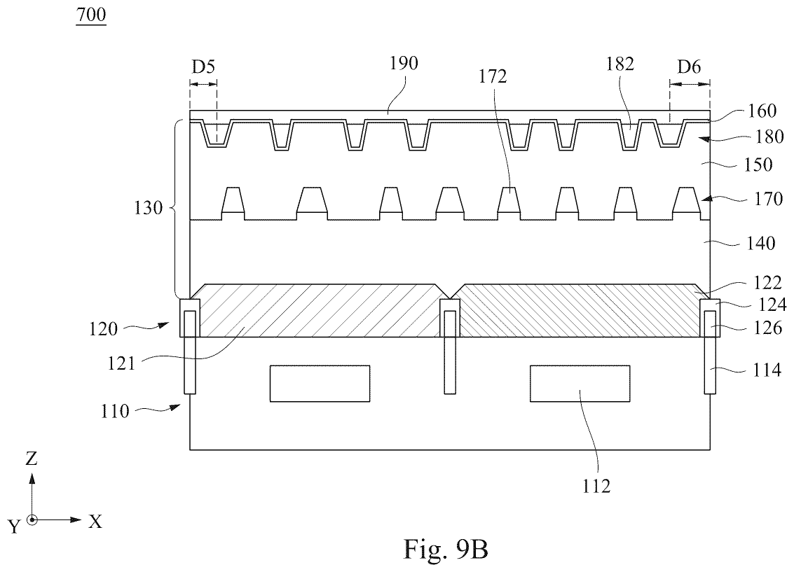

The image sensor 100 in FIG. 1 includes the first microstructure layer 170 as the tower shape microstructure layer and the second microstructure layer 180 as the funnel shape microstructure layer. In some other embodiments, the image sensor may include multiple tower shape microstructure layers between the spread layer and the funnel shape microstructure layer. According to one embodiment of the present disclosure, FIG. 7 illustrates a cross-sectional view of an image sensor 300 in the X-Z plane. The image sensor 300 is similar to the image sensor 100 in FIG. 1, except for a third microstructure layer 370 as the additional tower shape microstructure layer.

Specifically, the image sensor 300 includes a second transparent layer 350 interposed between the spread layer 140 and the first transparent layer 150 and the third microstructure layer 370 between the spread layer 140 and the second transparent layer 350. The first microstructure layer 170 and the third microstructure layer 370 are separated by the second transparent layer 350. The third microstructure layer 370 includes a plurality of third microstructures 372 embedded in a lower portion of the second transparent layer 350, where the bottom surfaces of the third microstructures 372 contact the top surface of the spread layer 140. Correspondingly, the bottom surfaces of the first microstructures 172 contact the top surface of the second transparent layer 350.

A refractive index of the third microstructure layer 370 is larger than the refractive indexes of the spread layer 140, the first transparent layer 150, and the second transparent layer 350. In other words, the microstructure layers in the optical layer 130 of the image sensor 300 have higher refractive indexes while the layers interposed between the microstructure layers have lower refractive indexes. In some embodiments, the first microstructure layer 170, the second microstructure layer 180, and the third microstructure layer 370 may have a same refractive index. The refractive index of the second transparent layer 350 may be same as or different from the refractive index of the first transparent layer 150, which both refractive indexes are larger than the refractive index of air.

The above-mentioned design of the first microstructure 172 may be applied to the third microstructure 372. The shape and the pattern of the third microstructures 372 may be same as or different from those of the first microstructures 172, depending on the light dispersion requirement of the optical layer 130. In addition, the shape and the pattern of the third microstructures 372 corresponding to the first color filter 121 may be different from those of the third microstructures 372 corresponding to the second color filter 122 due to the different wavelength ranges of the first color filter 121 and the second color filter 122.

The top surface of the second transparent layer 350 may include the top facets and the remaining portions interposed between the top facet top facets, where the top surfaces of the top facets are higher than the top surfaces of the remaining portions. The first microstructures 172 stand on the top facets of the second transparent layer 350, while the third microstructures 372 stand on the top facets of the spread layer 140. The thickness TH3 of the second transparent layer 350 between its top surface not covered by the first microstructures 172 and the top surface of the third microstructure layer 370 may be smaller than or equal to the absorption wavelength of the photodiode layer 110.

Referring back to FIG. 1, the image sensor 100 further includes a protection layer 190 on the top surface of the optical layer 130. The protection layer 190 having a flat top surface covers the top surfaces of the buffer layer 160 and the second microstructure layer 180 to provide a smooth incident surface for the image sensor 100. The protection layer 190 is illustrated as a single layer in FIG. 1, which is not necessary for every embodiment of the present disclosure. For example, FIGS. 8A-8B illustrate the cross-sectional views of an image sensor 400 and an image sensor 500, respectively, according to some other embodiments. The image sensor 400 in FIG. 8A includes a protection layer 190 with a multilayer structure made of organic layers and inorganic layers. The image sensor 500 in FIG. 8B is provided without the protection layer on the optical layer 130, where the top surface of the optical layer 130 may be a planar or non-planar surface.

As mentioned above, the pattern of the first microstructures 172 and the second microstructures 182 may contribute to the light dispersion function of the optical layer 130. In other words, the positions of the first microstructures 172 and the second microstructures 182 relative to color filter layer 120 may be adjusted to improve the light sensing effectivity of the image sensor 100.

According to one embodiment of the present disclosure, FIG. 9A illustrates a cross-sectional view of an image sensor 600 in the X-Z plane. The image sensor 600 is similar to the image sensor 100 in FIG. 1, except for the position of the optical layer 130 relative to the underlying layers. Specifically, the optical layer 130 of the image sensor 600 is shifted along the X-axis direction compared to the image sensor 100, such that the edge of the optical layer 130 of the image sensor 600 is offset from the edge of the color filter layer 120 by a distance D4. When the chief ray angle (CRA) of the component, such as lens, above the optical layer 130 and the chief ray angle of the photodiode layer 110 are mismatched, the offset optical layer 130 of the image sensor 600 may reduce the chief ray angle mismatch.

According to another embodiment of the present disclosure, FIG. 9B illustrates a cross-sectional view of an image sensor 700 in the X-Z plane. The image sensor 700 is similar to the image sensor 100 in FIG. 1, except for the patterns of the second microstructures 182. For example, some of the second microstructures 182 above the second color filter 122 of the image sensor 700 are inner-shifted toward the center of the second color filter 122, compared to the image sensor 100 in FIG. 1. As a result, a center of the second microstructure 182 nearest to an edge of the first color filter 121 is spaced apart from the edge of the first color filter 121 by a distance D5 along the X-axis direction, a center of the second microstructure 182 nearest to an edge of the second color filter 122 is spaced apart from the edge of the second color filter 122 by a distance D6 along the X-axis direction, and the distance D5 is different from the distance D6. Similarly, the pattern of the first microstructures 172 above the second color filter 122 may be different from that of the first microstructures 172 above the first color filter 121. The different patterns of the microstructures for the color filters, such as the first color filter 121 and the second color filter 122, within different wavelength range may improve the optical performance of the optical layer 130.

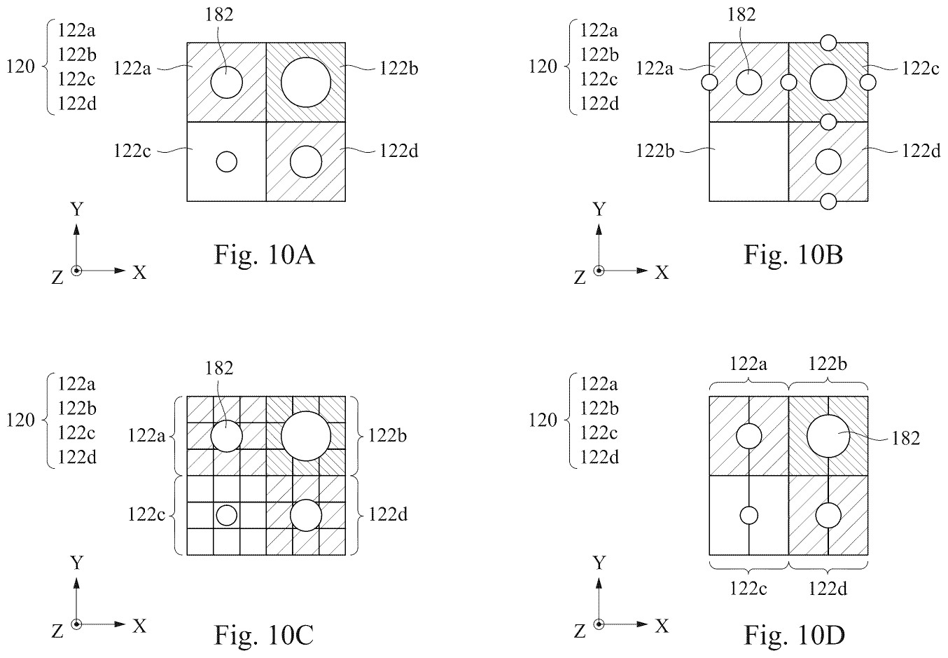

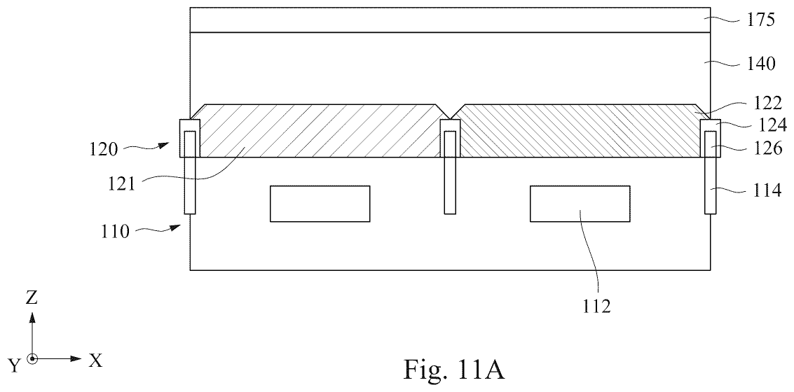

Accordingly, the dimensions, patterns of the first microstructure layer 170 and the second microstructure layer 180 may be adjusted to apply the optical layer 130 in various kinds of the image sensor. As exemplary illustrations, FIGS. 10A-10D illustrate the top views of different combinations of the second microstructures 182 and the color filter layer 120 in the X-Y plane. It should be noted that the description referring to FIGS. 10A-10D may also be applied to the relationship between the first microstructures 172 and the color filter layer 120.

The color filter layer 120 includes a first color filter 122a, a second color filter 122b adjacent to the first color filter 122a, a third color filter 122c adjacent to the first color filter 122a, and a fourth color filter 122d adjacent to the second color filter 122b and the third color filter 122c. Any adjacent two of the color filters in the color filter layer 120 may correspond to different wavelength range. For example, the color filter layer 120 may be a red-green-green-blue (RGGB) array, a red-green-blue-white RGBW array, a cyan-magenta-yellow (CMY) array, red-yellow-yellow-blue (RYYB) array, or red-green-blue-infrared (RGBIR) array.

In FIG. 10A, the patterns of the second microstructures 182 above the four color filters 122a-122d are the same, while the dimension of the second microstructure 182 above the first color filter 122a is different from those of the second microstructures 182 above the second color filter 122b and the third color filter 122c. The dimension of the second microstructure 182 above the first color filter 122a may be the same as that of the second microstructure 182 above the fourth color filter 122d when the first color filter 122a and the fourth color filter 122d have the same wavelength range. In FIG. 10B, the pattern of the second microstructures 182 is different from those of the second microstructures 182 above the second color filter 122b and the third color filter 122c.

The second microstructures 182 in FIG. 10A are applied to the image sensor with one-filter-one-photodiode structure. The second microstructures 182 in FIG. 10A may also be applied to the image sensor with multi-channel structure, such as the nine-channel (9C) illustrated for each color filter in the color filter layer 120 in FIG. 10C. The second microstructures 182 in FIG. 10A may also be applied to the image sensor with dual photodiode (DPD) structure, such as the dual rectangles illustrated for each color filter in the color filter layer 120 in FIG. 10D.

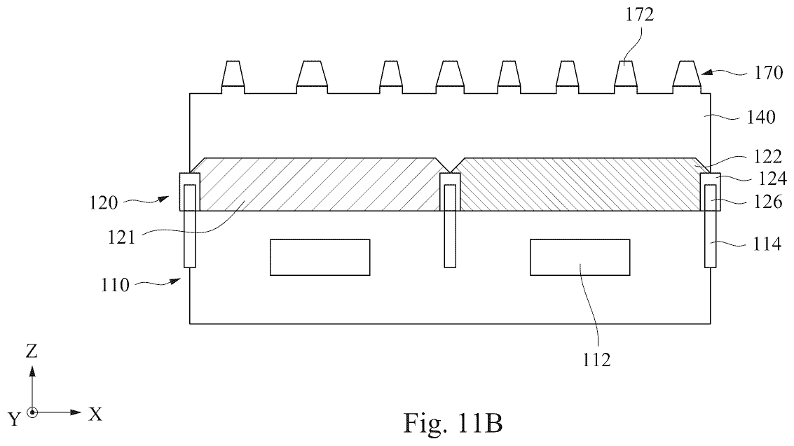

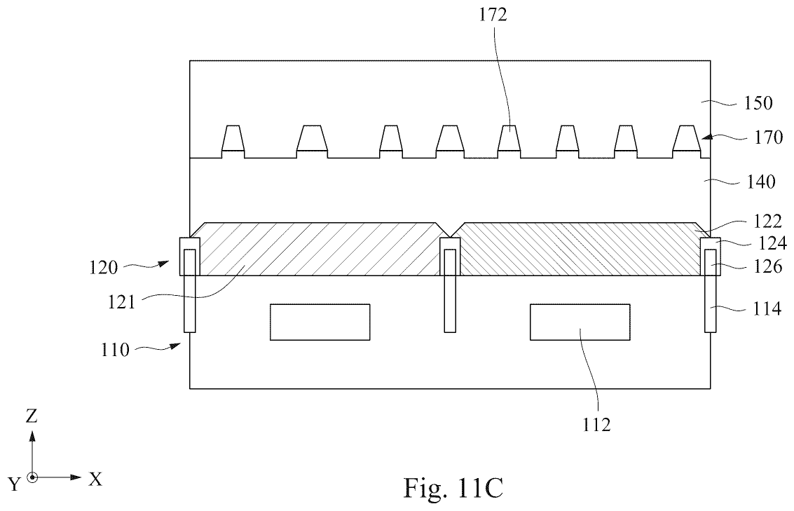

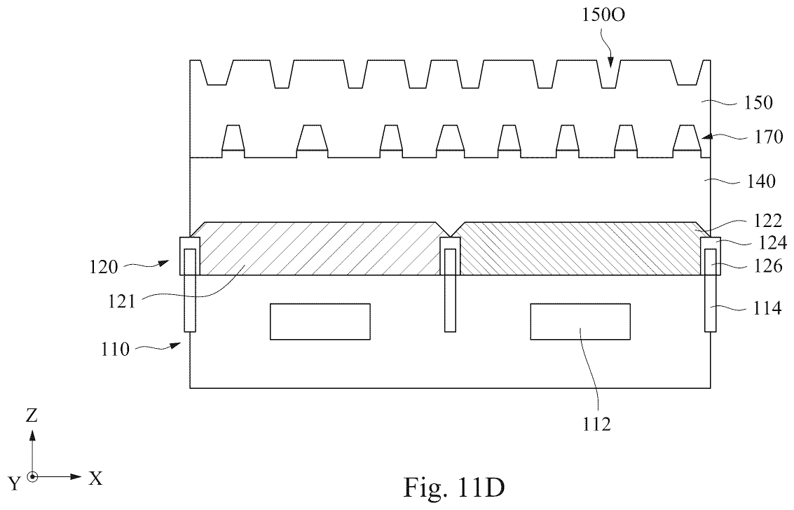

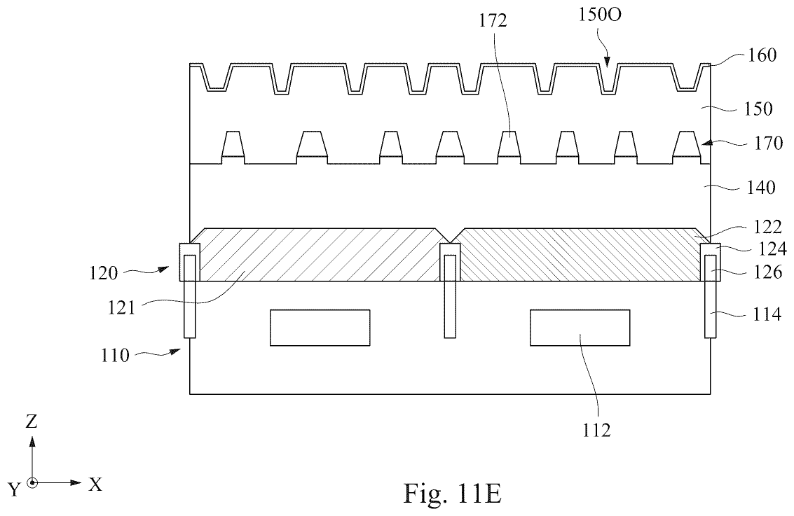

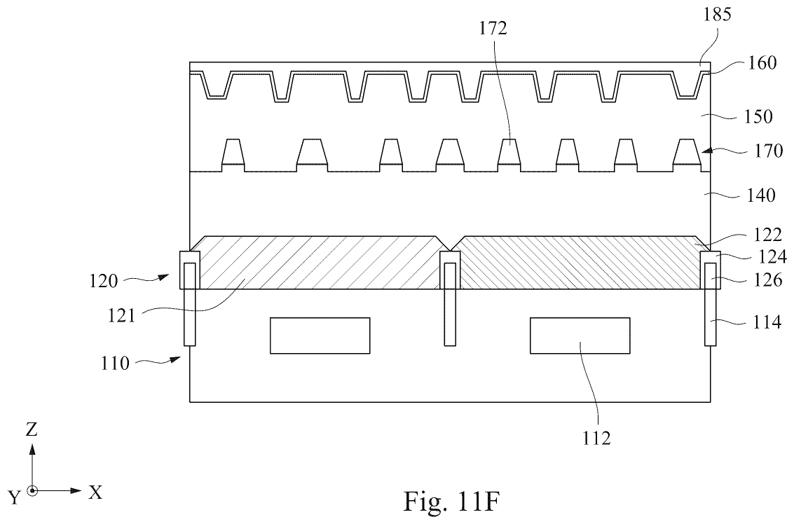

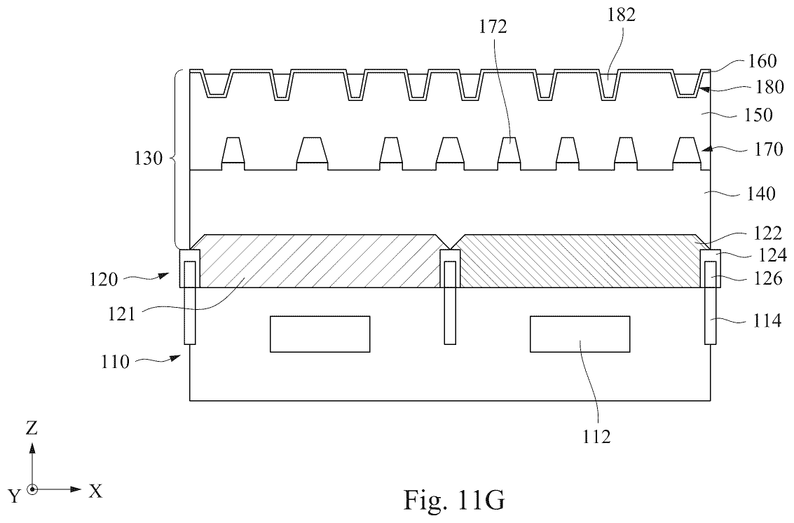

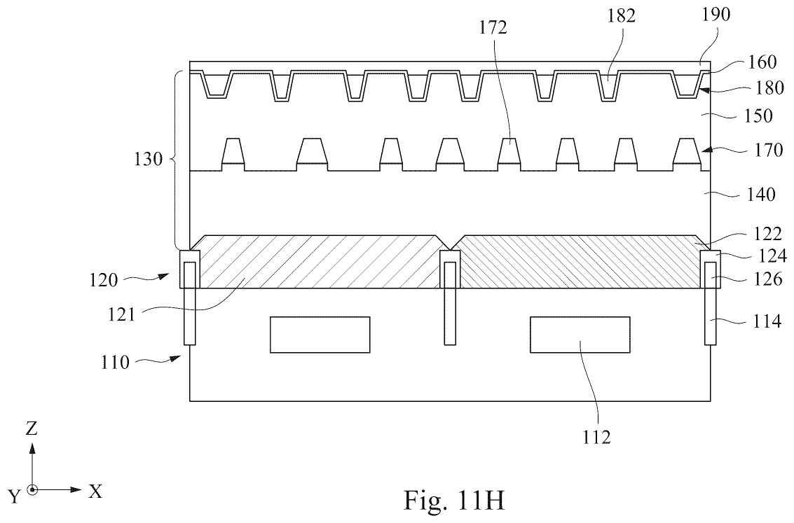

For illustrative purpose for the manufacturing of the optical layer, FIGS. 11A-11H illustrate the cross-sectional views of an image sensor at various stages in the manufacturing process according to some embodiments of the present disclosure. It should be noted that, unless otherwise stated, the description sequence of the steps illustrated in FIGS. 11A-11H should not be limited. For example, some steps may be taken in a different order than the described embodiments, some steps may occur simultaneously, some steps may not be required, and/or some steps may be repeated. In addition, additional steps may be performed before, during, or after the illustrated steps in FIGS. 11A-11H.

In FIG. 11A, a spread layer 140 and a first high-refractive index layer 175 is formed on the color filter layer 120. The spread layer 140 and the first high-refractive index layer 175 may be formed by coating or deposition process, such as chemical vapor deposition (CVD), plasma-enhanced CVD (PECVD), physical vapor deposition (PVD), or atomic layer deposition (ALD). The spread layer 140 and the first high-refractive index layer 175 may be formed as planar layers, where the first high-refractive index layer 175 will be patterned into the first microstructure layer 170.

In FIG. 11B, the first high-refractive index layer 175 is etched to form the first microstructures 172 of the first microstructure layer 170. The etching process may penetrate through the first high-refractive index layer 175 to form the separated first microstructures 172. The etching process may be an anisotropic dry etching operation. The spread layer 140 may also be etched to form the top facets under the first microstructures 172. The first microstructure layer 170 and the spread layer 140 may be etched in the same etching process or individually etched by different etchants.

In FIG. 11C, a first transparent layer 150 is formed on the spread layer 140 and the first microstructure layer 170. The first transparent layer 150 may be formed by coating or deposition process, such as chemical vapor deposition, plasma-enhanced CVD, physical vapor deposition, or atomic layer deposition. The first transparent layer 150 may fill the gaps between the first microstructures 172 and provide a planar top surface.

In FIG. 11D, openings 150O are formed in the first transparent layer 150, for example, by an etching process. The etching process is well controlled such that the openings 150O expose the interior of the first transparent layer 150 rather than the first microstructure layer 170.

In FIG. 11E, a buffer layer 160 is formed on the first transparent layer 150 and in the openings 150O. The buffer layer 160 may be formed by deposition process, such as chemical vapor deposition, plasma-enhanced CVD, physical vapor deposition, or atomic layer deposition. The openings 150O are not fully filled with the buffer layer 160, so a portion of the openings 150O is remained above the buffer layer 160 for the later formed second microstructures.

In FIGS. 11F-11G, a second high-refractive index layer 185 is formed on the buffer layer 160 and patterned into the second microstructure layer 180. The second high-refractive index layer 185 may be first formed by coating or deposition process, such as chemical vapor deposition, plasma-enhanced CVD, physical vapor deposition, or atomic layer deposition. The second high-refractive index layer 185 may fill the remaining openings 150O above the buffer layer 160 to form the second microstructures 182 of the second microstructure layer 180. Then, an etching process or a planarization process may be performed to remove the excessive material of the second high-refractive index layer 185, leaving the second microstructure layer 180 on the buffer layer 160.

After the steps illustrated in FIGS. 11A-11G, the optical layer 130 including the first microstructure layer 170 and the second microstructure layer 180 is formed. In FIG. 11H, a protection layer 190 may be formed on the second microstructure layer 180 to protect the optical layer 130. The protection layer 190 may be formed by coating or deposition process, such as chemical vapor deposition, plasma-enhanced CVD, physical vapor deposition, or atomic layer deposition. The protection layer 190 may fill the remaining openings 150O (if exist) above the second microstructures 182 and provide a planar top surface.

According to the above-mentioned embodiments, the image sensor of the present disclosure includes an optical layer above the photodiode layer and the color filter layer. The optical layer includes a spread layer, a transparent layer above the spread layer, a first microstructure layer including the first microstructures embedded in the transparent layer, and a second microstructure layer including the second microstructures embedded in the transparent layer. The refractive index of the two microstructure layers is larger than the refractive indexes of the transparent layer and the spread layer, so the wavelengths of the incident light may be refracted in different angles before reaching the color filter layer. The dimension, shape, and arrangement of the microstructures may contribute to the effective light dispersion of the optical layer, which improves the quantum efficiency of the image sensor and the compatibility of the optical layer with various kinds of image sensor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a photodiode layer;
a color filter layer on the photodiode layer; and
an optical layer on the color filter layer, comprising:
a spread layer;
a first transparent layer above the spread layer;
a buffer layer covering a top surface of the first transparent layer;
a first microstructure layer comprising first microstructures embedded in a lower portion of the first transparent layer; and
a second microstructure layer comprising second microstructures at least partially embedded in an upper portion of the first transparent layer, wherein the first microstructure layer and the second microstructure layer are separated by the first transparent layer and the buffer layer,
wherein a refractive index of the first microstructure layer and the second microstructure layer is larger than refractive indexes of the first transparent layer and the spread layer.

2. The image sensor of claim 1, wherein a refractive index of the buffer layer is smaller than the refractive index of the first microstructure layer and the second microstructure layer but larger than the refractive indexes of the first transparent layer and the spread layer.

3. The image sensor of claim 1, wherein the refractive indexes of the first transparent layer and the spread layer are larger than a refractive index of air.

4. The image sensor of claim 1, wherein a thickness of the first transparent layer between a top surface of the first microstructure layer and the buffer layer below a bottom surface of the second microstructure layer is smaller than or equal to an absorption wavelength of the photodiode layer.

5. The image sensor of claim 1, wherein each of the first microstructures stands on a top facet of the spread layer, and wherein a top surface of the top facet is higher than a top surface of a remaining portion of the spread layer.

6. The image sensor of claim 5, wherein a thickness of the remaining portion of the spread layer is smaller than or equal to three times of an absorption wavelength of the photodiode layer.

7. The image sensor of claim 5, wherein the top surface of the top facet is higher than the top surface of the remaining portion by a distance smaller than or equal to half of a height of the first microstructures.

8. The image sensor of claim 1, wherein a top surface of the second microstructure layer is lower than a top surface of the buffer layer by a distance smaller than or equal to half of a height of the second microstructures.

9. The image sensor of claim 1, wherein a top surface of the second microstructure layer is higher than a top surface of the buffer layer by a distance smaller than or equal to a height of the second microstructures.

10. The image sensor of claim 1, wherein each of the second microstructures has a bottom width smaller than or equal to a top width, a height smaller than or equal to eight times of the top width, and an angle between a sidewall and a bottom surface in a range of 90° to 160°.

11. The image sensor of claim 1, wherein each of the first microstructures has a top width smaller than or equal to a bottom width, a height smaller than or equal to eight times of the bottom width, and an angle between a sidewall and a bottom surface in a range of 50° to 90°.

12. The image sensor of claim 1, wherein each of the first microstructures and the second microstructures has a flat tip, a diamond tip, or a rounding tip.

13. The image sensor of claim 1, wherein the buffer layer conformally covers the top surface of the first transparent layer, sidewalls of the second microstructures, and bottom surfaces of the second microstructures.

14. The image sensor of claim 1, wherein the buffer layer has a portion below bottom surfaces of the second microstructures that is thicker than a portion of the buffer layer on sidewalls of the second microstructures.

15. The image sensor of claim 1, further comprising:
a second transparent layer interposed between the spread layer and the first transparent layer; and
a third microstructure layer comprising third microstructures embedded in a lower portion of the second transparent layer,
wherein a refractive index of the third microstructure layer is the same as the refractive index of the first microstructure layer and larger than a refractive index of the second transparent layer.

16. The image sensor of claim 15, wherein a thickness of the second transparent layer between a top surface of the third microstructure layer and a top surface of the second transparent layer is smaller than or equal to an absorption wavelength of the photodiode layer.

17. The image sensor of claim 1, wherein the color filter layer comprises a first color filter and a second color filter adjacent to the first color filter, and wherein a distance between a center of one of the second microstructures nearest to an edge of the first color filter and the edge of the first color filter is different from a distance between a center of one of the second microstructures nearest to an edge of the second color filter and the edge of the second color filter.

18. The image sensor of claim 1, wherein an edge of the optical layer is offset from an edge of the color filter layer.

19. The image sensor of claim 1, further comprising a protection layer covering a top surface of the second microstructure layer and having a flat top surface.

20. The image sensor of claim 1, wherein the color filter layer comprises a first color filter and a second color filter adjacent to the first color filter, and a pattern of the second microstructures above the first color filter is different from a pattern of the second microstructures above the second color filter.
